(19) United States
(12) Patent Application Publication
(10) Pub. No.: US 2003/0077882 A1
(43) Pub. Date: Apr. 24, 2003

(54) Method of forming strained-silicon wafer for mobility-enhanced MOSFET device

(75) Inventors: Wong-Cheng Shih, Kaohsiung (TW); Wenchi Ting, Taipei (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manfacturing Company

(21) Appl. No.: 09/912,736

(22) Filed: Jul. 26, 2001

(51) Int. Cl. H01L 21/36

(52) U.S. Cl. 438/478

(57) ABSTRACT

A method of fabricating a strained-silicon structure comprising the following steps. A substrate having an insulator layer formed thereover is provided. A silicon-on-insulator layer is formed over the insulator layer. A first SiGe layer is formed over the silicon-on-insulator layer. The first SiGe layer being strained. At least the first SiGe layer is annealed to convert the strained SiGe layer to a relaxed first SiGe layer. A second SiGe layer, having the same composition as the first SiGe layer, is formed over the first SiGe layer. The second SiGe layer being relaxed. An epitaxial silicon layer is grown over the second SiGe layer. The epitaxial silicon layer being strained to complete formation of the strained-silicon structure.

### BACKGROUND OF THE INVENTION

The performance of metal-oxide semiconductor field effect transistors (MOSFETs) is constantly driven by demands of high drive current and high speeds at low operating voltages. Given that the scaling down of gate devices for better performance is a huge task, alternative ways of improving MOSFET performance are sought.

In the developing new technology of strained-silicon (Si) MOSFET devices, it has been recently demonstrated that the carrier mobility for both electrons and holes in NMOS and PMOS, respectively, can be improved by as much as from 50 to 70% when compared with a normal Si MOSFET device of a given gate length. This mobility enhancement will give higher current drive and higher speed and this performance enhancement can be applied to 1.0 to 0.05 μm generation devices without a great deal of capital investment.

However, due to the fact that this strained-Si MOSFET device technology is relatively new, the availability of strained-Si wafers is very limited and those strained-Si wafers that are available from wafer providers are subject to the control of the wafer providers.

U.S. Pat. No. 5,759,898 to Ek et al. describes a process and method for producing strained and defect free semiconductor layers.

U.S. Pat. Nos. 6,059,895 to Chu et al. and 5,534,713 to Ismail et al. describe strained Si/SiGe layers in silicon-on-insulator (SOI) devices.

U.S. Pat. No. 6,191,432 to Sugiyama et al. describes an SOI process with a Si/Siₓ,Gel₁₋ₓ lattice for increased mobility.

U.S. Pat. No. 6,197,624 to Yamazaki describes an SOI device with strain added by ion implanting or ion doping and heat transfer lower than strain point.

U.S. Pat. No. 6,154,475 to Soref et al. describes an Si-based strained layer(s).

U.S. Pat. Nos. 5,659,187 to Legoues et al., 5,630,905 to Lynch et al., 6,111,267 to Fischer et al., 6,107,653 to Fitzgerald and 5,906,951 to Chu et al. describe related structures and processes.

### SUMMARY OF THE INVENTION

Accordingly, it is an object of one or more embodiments of the present invention to provide an improved method of fabricating strained-silicon structures.

### Other Objects will Appear Hereinafter.

It has now been discovered that the above and other objects of the present invention may be accomplished in the following manner. Specifically, a substrate having an insulator layer formed thereover is provided. A silicon-on-insulator layer is formed over the insulator layer. A first SiGe layer is formed over the silicon-on-insulator layer. The first SiGe layer being strained. At least the first SiGe layer is annealed to convert the strained SiGe layer to a relaxed first SiGe layer. A second SiGe layer, having the same composition as the first SiGe layer, is formed over the first SiGe layer. The second SiGe layer being relaxed. An epitaxial silicon layer is grown over the second SiGe layer. The epitaxial silicon layer being strained to complete formation of the strained-silicon structure.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 to 6 schematically illustrate a preferred embodiment of the present invention.

FIG. 7 schematically illustrates one use of the strained-Si structure formed in accordance with an embodiment of the present invention.

### DETAILED DESCRIPTION OF THE PREFERRED EMBODIMENT

Unless otherwise specified, all structures, layers, steps, methods, etc. may be formed or accomplished by conventional steps or methods known in the prior art.

### Initial Structure

Accordingly, as shown in FIG. 2, a thin silicon-on-insulator (SOI) structure 15 is formed over substrate 10 so that the silicon layer 14′ over the oxide layer 12 is preferably only from about 5 to 50 nm thick and more preferable from about 10 to 45 nm thick.

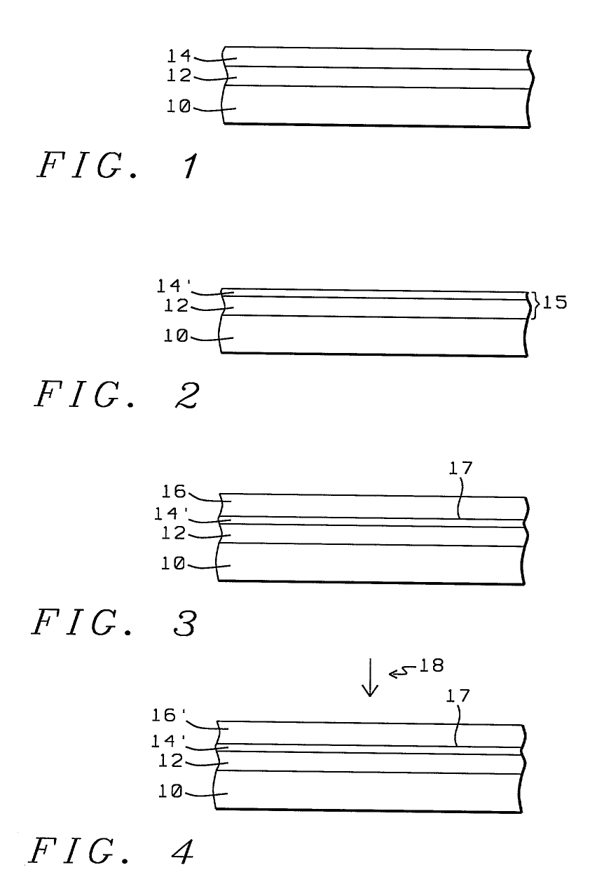

As shown in FIG. 1, a fully depleted SOI wafer may have its silicon layer 14 etched to reduce the Si layer 14 thickness as described above. For example, a thermal oxidation and etching process may be used to reduce the thickness of silicon layer 14 to the preferred thickness of silicon layer 14′ of the SOI structure 15 as shown in FIG. 2.

The SOI structure 15 of FIG. 2 is then cleaned, preferably with a chemical cleaning process and more preferably with a dilute HF acid cleaning process.

### Grow First Epitaxial Si₁₋ₓGeₓ Layer 16

As shown in FIG. 3, a first epitaxial Si₁₋ₓGeₓ layer 16 is grown over Si layer 14′ of SOI structure 15 where preferably 0.1<x<0.45 and more preferably 0.1<x<0.35. That is first Si₁₋ₓGeₓ layer 16 may be preferably from about Si₀₉Ge₀₁ to Si₀₅₅Ge₀₄₅; and more preferably from about Si₀₉Ge_{0.1} to Si₀₆₅Ge_{0.35}. Epitaxial first Si₁₋ₓGeₓ layer 16 is grown to a thickness of preferably from about 100 to 400 nm and more preferably from about 50 to 250 nm.

First epitaxial Si₁₋ₓGeₓ layer 16 is strained due to the differences in the crystalline structures between first Si layer 14′ and the Si₁₋ₓGeₓ being grown over first Si layer 14′ at the Si₁₋ₓGeₓ/Si interface 17.

### Anneal First Epitaxial Si₁₋ₓGeₓ layer 16

As shown in FIG. 4, the structure of FIG. 3 is annealed as at 18 to form dislocations at the Si₁₋ₓGeₓ/Si interface 17, reducing surface defects to relax the first Si₁₋ₓGeₓ layer 16 to form relaxed first Si₁₋ₓGeₓ layer 16′. The anneal 18 is conducted at preferably from about 800 to 1100° C. for from about 1 to 20 minutes and more preferably from about 850 to 1000° C. for from about 1 to 20 minutes.

After the anneal 18, the interface dislocation generated, and grew to the edge of the wafer. This relaxes the strain in the first Si₁₋ₓGeₓ layer 16 and also reduces the dislocation density at the Si₁₋ₓGeₓ surface at the Si₁₋ₓGeₓ/Si interface 17. Also, the Ge in the first Si₁₋ₓGeₓ layer 16 diffuses into the base first Si (SOI) layer 14′ which also relaxes the strain in the first Si₁₋ₓGeₓ layer 16 and slightly reduces the Ge concentration in the first Si₁₋ₓGeₓ layer 16. Because of these reasons, a newly grown second epitaxial Si₁₋ₓGeₓ layer 20 (see below) on top of the relaxed first Si₁₋ₓGeₓ layer 16′ is beneficial for the quality of the final Si layer (thin epitaxial Si layer 22).

An important consideration of the present invention is the concept of the interface Si₁₋ₓGeₓ/Si interface 17) dislocation formation due to the lattice mismatch and over the critical thickness. The addition of thermal energy (anneal 18) further facilitates formation of the interface dislocation. After formation of the interface dislocation, the strain in the film (first Si₁₋ₓGeₓ layer 16) is relaxed.

### Grow Second Epitaxial Si₁₋ₓGeₓ Layer 20

As shown in FIG. 5, a second epitaxial Si₁₋ₓGeₓ layer 20 (where x again=from about 0.1 to 0.35) is grown over relaxed first Si₁₋ₓGeₓ layer 16′ to a thickness of preferably from about 100 to 400 nm and more preferably from about 50 to 300 nm. Second and first Si₁₋ₓGeₓ layers 16′, 20 do not necessarily the same thickness. Second and first Si₁₋ₓGeₓ layers 16′, 20 have the same composition, i.e. e.g.: if first Si₁₋ₓGeₓ layer 16′=Si₀₈Ge₀₂ then second Si₁₋ₓGeₓ layer 20 also=Si₀₈Ge₀₂; and if first Si₁₋ₓGeₓ layer 16′=Si₀₇Ge₀₃ then second Si₁₋ₓGeₓ layer 20 also =Si₀₇Ge₀₃.

Since first Si₁₋ₓGeₓ layer 16′ is relaxed, second Si₁₋ₓGeₓ layer 20 is also relaxed.

### Grow Thin Epitaxial Si Layer 22

As shown in FIG. 6, thin epitaxial Si layer 22 is then grown over second relaxed Si₁₋ₓGeₓ layer 20 to a thickness of preferably from about 20 to 80 nm and more preferably from about 30 to 70 nm. Thin epitaxial Si layer 22 is strained due to the differences in the crystalline structures between the second relaxed Si₁₋ₓGeₓ layer 20 and the epitaxial Si being grown over second, relaxed Si₁₋ₓGeₓ layer 20 at the epitaxial Si/Si₁₋ₓGeₓ interface 21.

This completes fabrication of the strained-silicon wafer 30 in accordance with the present invention.

### Continued Processing

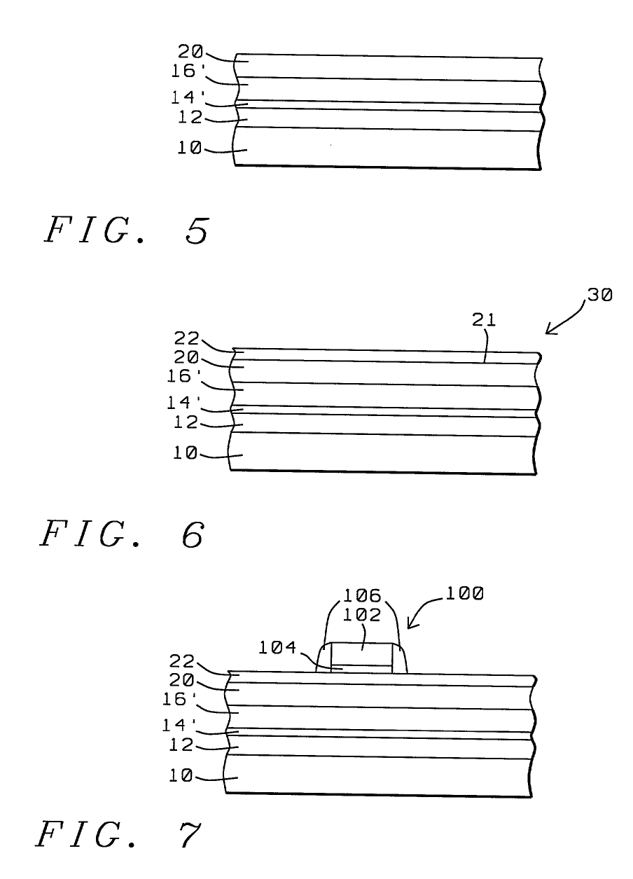

As shown in FIG. 7, further processing may proceed using the strained-Si wafer 30 formed in accordance with the present invention, and a mobility-enhanced MOSFET device 100, for example, may be formed over the strained-Si layer 22. Gate electrode structure 100 includes: gate electrode 102 formed over gate oxide layer 104 in turn formed over strained-Si layer 22; sidewall spacers 106 and source/drain implants (not shown).

### Advantages of the Present Invention

The advantages of one or more embodiments of the present invention include:

1. a simple way to provide strained-Si wafer;

2. the strained Si-wafer gives low dislocation density in the Si channel;

3. the strained Si-wafer produced in accordance with the present invention also gives the advantages of SOI (silicon-on-insulator) waters; and

4. the stained-Si devices produced using the strained Si-wafers produced in accordance with the present invention give high carrier mobility and high current drive for better device performance.

While particular embodiments of the present invention have been illustrated and described, it is not intended to limit the invention, except as defined by the following claims.

We claim:

1. A method of fabricating a strained-silicon structure, comprising the steps of:
providing a substrate having an insulator layer formed thereover;
forming a silicon-on-insulator layer over the insulator layer;
forming a first SiGe layer over the silicon-on-insulator layer; the first SiGe layer being strained;
annealing at least the first strained SiGe layer to convert the strained SiGe layer to a first relaxed SiGe layer;
forming a second SiGe layer having the same composition as the first SiGe layer over the first relaxed SiGe layer; the second SiGe layer being relaxed; and
growing an epitaxial silicon layer over the second relaxed SiGe layer; the epitaxial silicon layer being strained to complete formation of the strained-silicon structure.

2. The method of claim 1, wherein the silicon-on-insulator layer has a thickness of from about 5 to 50 nm; the first SiGe layer has a thickness of from about 100 to 400 nm; the second SiGe layer having a thickness of from about 100 to 400 nm; and the epitaxial silicon layer having a thickness of from about 20 to 80 nm.

3. The method of claim 1, wherein the silicon-on-insulator layer has a thickness of from about 10 to 45 nm; the first SiGe layer has a thickness of from about 50 to 250 nm; the second SiGe layer having a thickness of from about 50 to 300 nm; and the epitaxial silicon layer having a thickness of from about 30 to 70 nm.

4. The method of claim 1, wherein the silicon-on-insulator is cleaned before formation of the first SiGe layer.

5. The method of claim 1, wherein the silicon-on-insulator is cleaned with dilute HF acid before formation of the first SiGe layer.

6. The method of claim 1, wherein the first and second SiGe layers have the composition Si₁₋ₓGeₓ where 0.1<x<0.45.

7. The method of claim 1, wherein the first and second SiGe layers have the composition Si₁₋ₓGeₓ where 0.1<x<0.35.

8. The method of claim 1, wherein the first SiGe layer is annealed at a temperature of from about 800 to 1100° C. for from about 1 to 20 minutes.

9. The method of claim 1, wherein the first SiGe layer is annealed at a temperature of from about 850 to 1000° C. for from about 1 to 20 minutes.

10. The method of claim 1, wherein the first and second SiGe layers are epitaxially grown.

11. The method of claim 1, including the step of forming a semiconductor structure over the strained-silicon structure.

12. The method of claim 1, wherein the substrate is a silicon substrate.

13. The method of claim 1, wherein the substrate is a silicon wafer.

14. A method of fabricating a strained-silicon structure, comprising the steps of:
providing a substrate having an insulator layer formed thereover;
forming a silicon-on-insulator layer over the insulator layer;
forming a first Si₁₋ₓGeₓ layer over the silicon-on-insulator layer where 0.1<x<0.45; the first Si₁₋ₓGeₓ layer being strained;
annealing at least the first Si₁₋ₓGeₓ layer to convert the strained Si₁₋ₓGeₓ layer to a first relaxed Si₁₋ₓGeₓ layer;
forming a second Si₁₋ₓGeₓ layer having the same composition as the first Si₁₋ₓGeₓ layer over the first Si₁₋ₓGeₓ layer; the second Si₁₋ₓGeₓ layer being relaxed; and
growing an epitaxial silicon layer over the second Si₁₋ₓGeₓ layer; the epitaxial silicon layer being strained to complete formation of the strained-silicon structure.

15. The method of claim 14, wherein the silicon-on-insulator layer has a thickness of from about 5 to 50 nm; the first Si₁₋ₓGeₓ layer has a thickness of from about 100 to 400 nm; the second Si₁₋ₓGeₓ layer having a thickness of from about 100 to 400 nm; and the epitaxial silicon layer having a thickness of from about 20 to 80 nm.

16. The method of claim 14, wherein the silicon-on-insulator layer has a thickness of from about 10 to 45 nm; the first Si₁₋ₓGeₓ layer has a thickness of from about 50 to 250 nm; the second Si₁₋ₓGeₓ layer having a thickness of from about 50 to 300 nm; and the epitaxial silicon layer having a thickness of from about 30 to 70 nm.

17. The method of claim 14, wherein the silicon-on-insulator is cleaned before formation of the first Si₁₋ₓGeₓ layer.

18. The method of claim 14, wherein the silicon-on-insulator is cleaned with dilute HF acid before formation of the first Si₁₋ₓGeₓ layer.

19. The method of claim 14, wherein 0.1<x<0.35.

20. The method of claim 14, wherein the first Si₁₋ₓGeₓ layer is annealed at a temperature of from about 800 to 1100° C. for from about 1 to 20 minutes.

21. The method of claim 14, wherein the first Si₁₋ₓGeₓ layer is annealed at a temperature of from about 850 to 1000° C. for from about 1 to 20 minutes.

22. The method of claim 14, wherein the first and second Si₁₋ₓGeₓ layers are epitaxially grown.

23. The method of claim 14, including the step of forming a semiconductor structure over the strained-silicon structure.

24. The method of claim 14, wherein the substrate is a silicon substrate.

25. The method of claim 14, wherein the substrate is a silicon wafer.

26. A method of fabricating a strained-silicon structure, comprising the steps of:
providing a substrate having an insulator layer formed thereover;
forming a silicon-on-insulator layer upon the insulator layer; the silicon-on-insulator layer having a thickness of from about 5 to 50 nm;
forming a first Si₁₋ₓGeₓ layer upon the silicon-on-insulator layer where 0.1<x <0.45; the first Si₁₋ₓGeₓ layer being strained; the first Si₁₋ₓGeₓ layer 16 having a thickness of from about 100 to 400 nm;
annealing at least the first Si₁₋ₓGeₓ layer to convert the strained Si₁₋ₓGeₓ layer to a first relaxed Si₁₋ₓGeₓ layer;
forming a second Si₁₋ₓGeₓ layer having the same composition as the first Si₁₋ₓGeₓ layer upon the first Si₁₋ₓGeₓ layer; the second Si₁₋ₓGeₓ layer being relaxed; the second Si₁₋ₓGeₓ layer having a thickness of from about 100 to 400 nm; and
growing an epitaxial silicon layer upon the second Si₁₋ₓGeₓ layer; the epitaxial silicon layer being strained to complete formation of the strained-silicon structure; the epitaxial silicon layer having a thickness of from about 20 to 80 nm.

27. The method of claim 26, wherein the silicon-on-insulator layer has a thickness of from about 10 to 45 nm; the first Si₁₋ₓGeₓ layer has a thickness of from about 50 to 250 nm; the second Si₁₋ₓGeₓ layer having a thickness of from about 50 to 300 nm; and the epitaxial silicon layer having a thickness of from about 30 to 70 nm.

28. The method of claim 26, wherein the silicon-on-insulator is cleaned before formation of the first Si₁₋ₓGeₓ layer.

29. The method of claim 26, wherein the silicon-on-insulator is cleaned with dilute HF acid before formation of the first Si₁₋ₓGeₓ layer.

30. The method of claim 26, wherein 0.1<x<0.35.

31. The method of claim 26, wherein the first Si₁₋ₓGeₓ layer is annealed at a temperature of from about 800 to 1100° C. for from about 1 to 20 minutes.

32. The method of claim 26, wherein the first Si₁₋ₓGeₓ layer is annealed at a temperature of from about 850 to 1000° C. for from about 1 to 20 minutes.

33. The method of claim 26, wherein the first and second Si₁₋ₓGeₓ layers are epitaxially grown.

34. The method of claim 26, including the step of forming a semiconductor structure over the strained-silicon structure.

35. The method of claim 26, wherein the substrate is a silicon substrate.

36. The method of claim 26, wherein the substrate is a silicon wafer.
